(19) United States
(12) Patent Application Publication
(10) Pub. No.: US 2024/0321998 A1
(43) Pub. Date: Sep. 26, 2024

(54) SEMICONDUCTOR STRUCTURE

(71) Applicant: E Ink Holdings Inc., Hsinchu (TW)

(72) Inventors: Ming-Kai Chuang, Hsinchu (TW); Huai-Cheng Lin, Hsinchu (TW); Ming-Sheng Chiang, Hsinchu (TW); Lih-Hsiung Chan, Hsinchu (TW)

(73) Assignee: E Ink Holdings Inc., Hsinchu (TW)

(21) Appl. No.: 18/444,778

(22) Filed: Feb. 19, 2024

Related U.S. Application Data
(60) Provisional application No. 63/453,164, filed on Mar. 20, 2023.

(51) Int. Cl. H01L 29/51; H01L 29/786

(52) U.S. Cl. CPC H01L 29/513; H01L 29/78669

(57) ABSTRACT

A semiconductor structure includes a gate, an active layer, a gate insulator layer, a source, and a drain. The active layer has a source region, a drain region, and a channel region. The semiconductor structure satisfies at least one of the following conditions: (1) a material of the active layer includes a-Si, and a first thickness and a second thickness of the active layer respectively in the source region and the drain region are respectively greater than a third thickness of the active layer in the channel region; (2) the gate insulator layer includes a first gate insulator layer, a third gate insulator layer, and a second gate insulator layer located between the first and third gate insulator layers. A material of the first gate insulator layer is identical to a material of the third gate insulator layer but different from a material of the second gate insulator layer.

### CROSS-REFERENCE TO RELATED APPLICATION

This application claims the priority benefit of U.S. Provisional application Ser. No. 63/453,164, filed on Mar. 20, 2023. The entirety of the above-mentioned patent application is hereby incorporated by reference herein and made a part of this specification.

### BACKGROUND

### Technical Field

The disclosure relates to a semiconductor structure, and particularly to a semiconductor structure capable of effectively suppressing leakage current.

### Description of Related Art

Presently, amorphous silicon thin film transistors (a-Si TFTs) exhibit a notable issue of heightened leakage current when operated at high voltages, and this leakage phenomenon exacerbates as an increasing voltage (Vds) between a source and a drain. In response to this challenge, four potential solutions have been proposed: (1) modulating the Vcom value to create a substantial voltage difference between upper and lower electrode layers within an ink layer: a drawback of this method is that it results in a sluggish screen refresh rate, thereby limiting the range of practical applications; (2) series connection of two transistors: this necessitates a reduction in an area occupied by a storage capacitor due to the addition of an extra transistor, thus reducing the storage capacitance and resulting in an insufficient charging rate of the storage capacitor in high-resolution or T-wire products; (3) introducing an additional electrode to provide supplementary bias: this approach cannot seamlessly integrate with the existing technology, leading to increased complexity in panel driving and increased development and manufacturing costs; (4) off-set drain design: where the drain is displaced from the gate, resulting in an asymmetric transistor structure. However, this design may not be well-suited for high-resolution products, and it may contribute to a reduction in the storage capacitance. Moreover, the application of different voltage conditions to the source and the drain may yield varying electrical properties, introducing asymmetry and increasing practical usage difficulties.

### SUMMARY

This disclosure provides a semiconductor structure that is able to effectively reduce/suppress leakage current while the semiconductor structure is driven under a high voltage.

In an embodiment of the disclosure, a semiconductor structure including a gate, an active layer, a gate insulator layer, a source, and a drain is provided. The active layer is disposed on the gate and has a source region, a drain region, and a channel region located between the source region and the drain region. The gate insulator layer is disposed between the gate and the active layer. The source is disposed above the source region and extends onto the gate insulator layer. The drain is disposed above the drain region and extends onto the gate insulator layer. The semiconductor structure at least satisfies one of following conditions: (1) a material of the active layer includes amorphous silicon (a-Si), and a first thickness of the active layer in the source region and a second thickness of the active layer in the drain region are respectively greater than a third thickness of the active layer in the channel region; (2) the gate insulator layer includes a first gate insulator layer, a second gate insulator layer, and a third gate insulator layer, the second gate insulator layer is located between the first gate insulator layer and the third gate insulator layer, and a material of the first gate insulator layer is the same as a material of the third gate insulator layer, while a material of the second gate insulator layer is different from the material of the first gate insulator layer.

According to an embodiment of the disclosure, the first thickness is equal to the second thickness, the third thickness is less than the first thickness, and the third thickness is less than 1500 angstroms.

According to an embodiment of the disclosure, the first gate insulator layer has a first insulation thickness, the second gate insulator layer has a second insulation thickness, the third gate insulator layer has a third insulation thickness, and the second insulation thickness is less than the first insulation thickness and the third insulation thickness.

According to an embodiment of the disclosure, the first insulation thickness is greater than the third insulation thickness.

According to an embodiment of the disclosure, the second gate insulator layer is a plasma treatment layer.

According to an embodiment of the disclosure, a material of the plasma treatment layer includes silicon oxide, aluminum oxide, or titanium oxide.

According to an embodiment of the disclosure, a material of the first gate insulator layer and a material of the third gate insulator layer include silicon nitride, respectively.

According to an embodiment of the disclosure, the first gate insulator layer, the second gate insulator layer, and the third gate insulator layer are sequentially stacked on the gate.

According to an embodiment of the disclosure, the first gate insulator layer, the second gate insulator layer, and the third gate insulator layer are arranged in a coplanar manner.

According to an embodiment of the disclosure, the semiconductor structure further includes an ohmic contact layer that is disposed between the source region of the active layer and the source and between the drain region of the active layer and the drain.

In light of the foregoing, the design of the semiconductor structure provided in one or more embodiments of the disclosure satisfies at least one of the following conditions: (1) the material of the active layer includes a-Si, and the first thickness of the active layer in the source region and the second thickness of the active layer in the drain region respectively exceed the third thickness of the active layer in the channel region; (2) the gate insulator layer includes the first gate insulator layer, the second gate insulator layer, and the third gate insulator layer, the second gate insulator layer is located between the first gate insulator layer and the third gate insulator layer, and the material of the first gate insulator layer is the same as the material of the third gate insulator layer, while the material of the second gate insulator layer is different from the material of the first gate insulator layer. Therefore, under high voltage driving, the semiconductor structure provided in one or more embodiments of the disclosure is able to effectively reduce/suppress leakage current, so that the semiconductor structure is adapted to products with high voltage driving requirements, such as electrophoretic display panels (EPD), gate driver on array (GOA), or the like.

In order to make the above-mentioned features and advantages of the disclosure comprehensible, embodiments accompanied with drawings are described in detail below.

### BRIEF DESCRIPTION OF THE DRAWINGS

The accompanying drawings, which are included to provide a further understanding of the disclosure, are incorporated in and constitute a part of this specification. The drawings illustrate embodiments of the disclosure and, together with the description, serve to explain the principles of the disclosure.

FIG. 1 is a schematic cross-sectional view illustrating a semiconductor structure according to an embodiment of the disclosure.

FIG. 2 is a schematic cross-sectional view illustrating a semiconductor structure according to another embodiment of the disclosure.

FIG. 3 is a schematic cross-sectional view illustrating a semiconductor structure according to another embodiment of the disclosure.

FIG. 4 is a curve diagram illustrating a voltage and a current of a semiconductor structure according to an embodiment of the disclosure.

### DESCRIPTION OF THE EMBODIMENTS

Reference will now be made in detail to the exemplary embodiments of the disclosure, and examples of the exemplary embodiments are illustrated in the accompanying drawings. It should be understood that certain elements in the drawings may not be drawn to scale. As a matter of fact, for clear descriptions, the dimension of respective features may be arbitrarily enlarged or reduced.

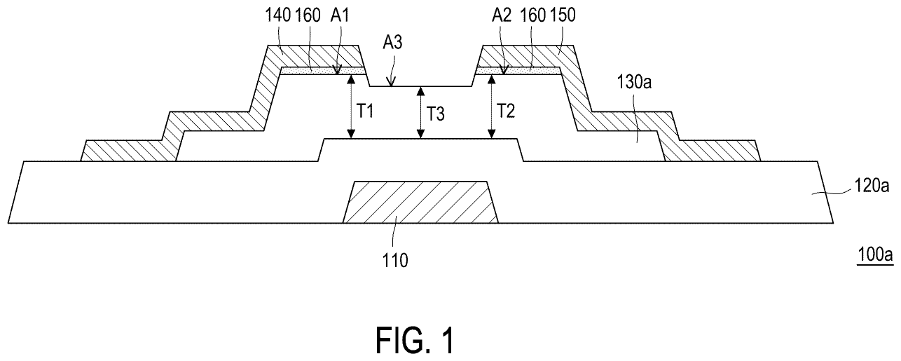

FIG. 1 is a schematic cross-sectional view illustrating a semiconductor structure according to an embodiment of the disclosure. With reference to FIG. 1, in the present embodiment, a semiconductor structure 100a includes a gate 110, a gate insulator layer 120a, an active layer 130a, a source 140, and a drain 150. The active layer 130a is disposed on the gate 110 and has a source region A1, a drain region A2, and a channel region A3 located between the source region A1 and the drain region A2. The gate insulator layer 120a is disposed between the gate 110 and the active layer 130a. The source 140 is disposed above the source region A1 and extends onto the gate insulator layer 120a. The drain 150 is disposed above the drain region A2 and extends onto the gate insulator layer 120a. Specifically, in the present embodiment, a material of the active layer 130a includes a-Si, and a first thickness T1 of the active layer 130a in the source region A1 and a second thickness T2 of the active layer 130a in the drain region A2 are respectively greater than a third thickness T3 of the active layer 130a in the channel region A3.

In particular, as shown in FIG. 1, the semiconductor structure 100a, which is composed of the gate 110, the gate insulator layer 120a, the active layer 130a, the source 140, and the drain 150, is specifically embodied as a bottom type a-Si thin film transistor (a-Si TFT), which should however not be construed as a limitation in the disclosure. In another embodiment not shown in the drawings, the semiconductor structure may also be a coplanar a-Si TFT structure, an inverted coplanar a-Si TFT structure, a staggered a-Si TFT structure, or an inverted staggered a-Si TFT structure. Here, a material of the gate 110, a material of the source 140, and a material of the drain 150 may include, for instance, alloys, nitrides of metal materials, oxides of metal materials, oxynitrides of metal materials, other suitable materials, or a stacked layer of metal materials and other conductive materials. A material of the gate insulator layer 120a may include, for instance, silicon oxide, silicon nitride, silicon oxynitride, other dielectric materials, or a stacked layer of these materials.

As shown in FIG. 1, in the active layer 130a, the first thickness T1 in the source region A1 may be equal to the second thickness T2 in the drain region A2, and the third thickness T3 in the channel region A3 is less than the first thickness T1. In an embodiment of the disclosure, the third thickness T3 is less than 1500 angstroms. That is, the third thickness T3 of the active layer 130a in the channel region A3 is thinned down to be below 1500 angstroms as compared to the first thickness T1 in the source region A1 and the second thickness T2 in the drain region A2. In general, dangling bonds are prone to excite electrons in weak bond region under a high voltage, thus resulting in leakage current. Therefore, the semiconductor structure 100a provided in the present embodiment reduces/suppresses the leakage current generated under the high voltage by thinning down the third thickness T3 of the active layer 130a in the channel region A3, i.e., reducing the volume, so as to reduce the number of the dangling bonds.

In addition, the semiconductor structure 100a provided in the present embodiment further includes an ohmic contact layer 160 that is disposed between the source region A1 of the active layer 130a and the source 140 and between the drain region A2 of the active layer 130a and the drain 150. Here, a material of the ohmic contact layer 160 may include a highly doped n-type a-Si material, which should however not be construed as a limitation in the disclosure.

It should be noted that reference numbers of the devices and a part of contents of the previous embodiments are also used in the following embodiments, where the same reference numbers denote the same or like devices, and descriptions of the same technical contents are omitted. The previous embodiments may be referred for descriptions of the omitted parts, and detailed descriptions thereof are not repeated in the following embodiments.

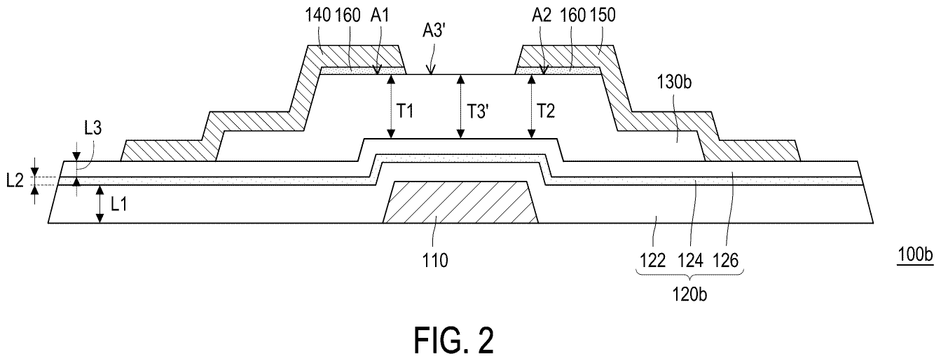

FIG. 2 is a schematic cross-sectional view illustrating a semiconductor structure according to another embodiment of the disclosure. With reference to FIG. 1 and FIG. 2, a semiconductor structure 100b provided in the present embodiment is similar to the above-mentioned semiconductor structure 100a, and the difference between the two lies in that a structural design of a gate insulator layer 120b and an active layer 130b in the present embodiment is different from the structural design of the above-mentioned gate insulator layer 120a and active layer 130a.

Particularly, in the present embodiment, a material of the active layer 130b includes a-Si, where the first thickness T1 of the active layer 130b in the source region A1, the second thickness T2 in the drain region A2, and a third thickness T3′ in a channel region A3′ are all the same, meaning that the third thickness T3′ of the active layer 130b in the channel region A3′ has not been thinned down. Besides, the gate insulator layer 120b provided in the present embodiment includes a first gate insulator layer 122, a second gate insulator layer 124, and a third gate insulator layer 126. The second gate insulator layer 124 is located between the first gate insulator layer 122 and the third gate insulator layer 126, where the first gate insulator layer 122, the second gate insulator layer 124, and the third gate insulator layer 126 are sequentially stacked on the gate 110. In the present embodiment, the first gate insulator layer 122, the second gate insulator layer 124, and the third gate insulator layer 126 are arranged in a coplanar manner, which should however not be construed as a limitation. In another embodiment, the second gate insulator layer 124 may also be a patterned insulator layer; that is, the second gate insulator layer 124 does not entirely cover the first gate insulator layer 122. Here, the second gate insulator layer 124 may merely be located in a region corresponding to the channel region A3.

Additionally, a material of the first gate insulator layer 122 is the same as a material of the third gate insulator layer 126, while a material of the second gate insulator layer 124 is different from the material of the first gate insulator layer 122. The materials of the first gate insulator layer 122 and the third gate insulator layer 126 include, for instance, silicon nitride. Specifically, the second gate insulator layer 124 is embodied as a plasma treatment layer, where a material of the plasma treatment layer includes, for instance, silicon oxide, aluminum oxide, or titanium oxide. In an embodiment, the plasma treatment layer may be formed by oxygen plasma, hydrogen plasma, nitrogen plasma, NH3 plasma, PH4 plasma, SiH4 plasma, and so on. With reference to FIG. 2, the first gate insulator layer 122 has a first insulation thickness L1, the second gate insulator layer 124 has a second insulation thickness L2, and the third gate insulator layer 126 has a third insulation thickness L3, where the second insulation thickness L2 is less than the first insulation thickness L1 and the third insulation thickness L3, and the first insulation thickness L1 is greater than the third insulation thickness L3.

In brief, according to the present embodiment, the plasma-treated second gate insulator layer 124 is disposed between the first gate insulator layer 122 and the third gate insulator layer 126, so as to form a carrier trapping layer in advance in the gate insulator layer 120b. Therefore, when a high voltage is applied, the leakage current of the channel region A3′ ahead is trapped in the gate insulator layer 120b due to a tunneling effect and is not conducted between the source 140 and the drain 150. Accordingly, the semiconductor structure 100b is allowed to reduce/suppress the leakage current under high voltage driving.

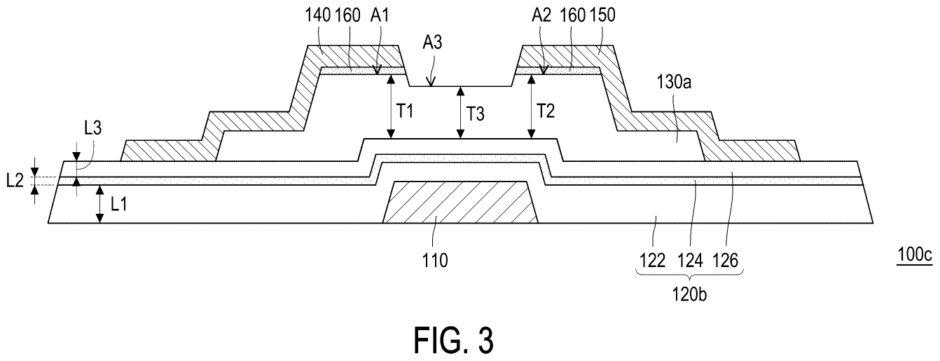

FIG. 3 is a schematic cross-sectional view illustrating a semiconductor structure according to another embodiment of the disclosure. With reference to FIG. 1 and FIG. 3, a semiconductor structure 100c provided in the present embodiment is similar to the above-mentioned semiconductor structure 100a, and the difference between the two lies in that the gate insulator layer 120b provided in the present embodiment includes the first gate insulator layer 122, the second gate insulator layer 124, and the third gate insulator layer 126. The second gate insulator layer 124 is located between the first gate insulator layer 122 and the third gate insulator layer 126, where the first gate insulator layer 122, the second gate insulator layer 124, and the third gate insulator layer 126 are sequentially stacked on the gate 110. In the present embodiment, the first gate insulator layer 122, the second gate insulator layer 124, and the third gate insulator layer 126 are arranged in a coplanar arrangement, which should however not be construed as a limitation in the disclosure. In another embodiment, the second gate insulator layer 124 may also be a patterned insulator layer; that is, the second gate insulator layer 124 does not entirely cover the first gate insulator layer 122.

Additionally, a material of the first gate insulator layer 122 is the same as a material of the third gate insulator layer 126, while a material of the second gate insulator layer 124 is different from the material of the first gate insulator layer 122. The materials of the first gate insulator layer 122 and the third gate insulator layer 126 include, for instance, silicon nitride. Specifically, the second gate insulator layer 124 is embodied as a plasma treatment layer, where a material of the plasma treatment layer includes, for instance, silicon oxide, aluminum oxide, or titanium oxide. In an embodiment, the plasma treatment layer may be formed by oxygen plasma, hydrogen plasma, nitrogen plasma, NH3 plasma, PH4 plasma, SiH4 plasma, and so on. With reference to FIG. 3, the first gate insulator layer 122 has the first insulation thickness L1, the second gate insulator layer 124 has the second insulation thickness L2, and the third gate insulator layer 126 has the third insulation thickness L3, where the second insulation thickness L2 is less than the first insulation thickness L1 and the third insulation thickness L3, and the first insulation thickness L1 is greater than the third insulation thickness L3.

In brief, in the semiconductor structure 100c provided in the present embodiment, the leakage current generated under the high voltage is reduced/suppressed by thinning down the third thickness T3 of the active layer 130a in the channel region A3, i.e., reducing the volume, so as to reduce the number of the dangling bonds; besides, the plasma-treated second gate insulator layer 124 is disposed between the first gate insulator layer 122 and the third gate insulator layer 126, so as to form a carrier trapping layer in advance in the gate insulator layer 120b. Therefore, when a high voltage is applied, the leakage current of the channel region A3′ ahead is trapped in the gate insulator layer 120b due to a tunneling effect and is not conducted between the source 140 and the drain 150. Accordingly, the semiconductor structure 100c is allowed to reduce/suppress the leakage current under high voltage driving.

The semiconductor structures 100a, 100b, and 100c provided in the present embodiment at least satisfy one of the following conditions: (1) the material of the active layer 130a includes a-Si, and the first thickness T1 of the active layer 130a in the source region A1 and the second thickness T2 of the active layer 130a in the drain region A2 are both greater than the third thickness T3 of the active layer 130a in the channel region A3; (2) the gate insulator layer 120b includes the first gate insulator layer 122, the second gate insulator layer 124, and the third gate insulator layer 126, the second gate insulator layer 124 is located between the first gate insulator layer 122 and the third gate insulator layer 126, and the material of the first gate insulator layer 122 is the same as the material of the third gate insulator layer 126, while the material of the second gate insulator layer 124 is different from the material of the first gate insulator layer 122. Therefore, under high voltage driving, the semiconductor structures 100a, 100b, and 100c provided in the present embodiment may effectively reduce/suppress the leakage current.

In terms of application, since the semiconductor structures 100a, 100b, and 100c are able to effectively reduce/suppress the leakage current under high voltage driving, the semiconductor structures 100a, 100b, and 100c are adapted to EPD products, such as color EPD or black-and-white EPD that allows fast page flipping. In addition, the semiconductor structures 100a, 100b, and 100c may also be applied to GOA products.

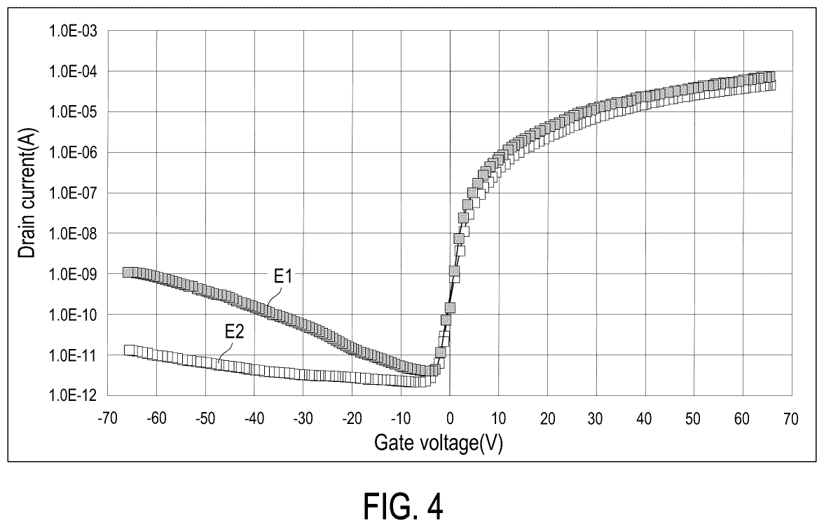

FIG. 4 is a curve diagram illustrating a voltage and a current of a semiconductor structure according to an embodiment of the disclosure. With reference to FIG. 4, a curve E1 represents two conventional serially connected a-Si TFTs, while a curve E2 represents two serially connected semiconductor structures 100a (or two serially connected semiconductor structures 100b or two serially connected semiconductor structures 100c) of the present embodiment. When a voltage difference between the source and drain is 50 volts (V), in a region where the gate voltage is above-35 V, the curve E1 indicates a significant leakage current (i.e., the drain current is greater than 1.0E-10 amperes (A)), while the curve E2 indicates an effective suppression of the leakage current.

To sum up, the design of the semiconductor structure provided in one or more embodiments of the disclosure satisfies at least one of the following conditions: (1) the material of the active layer includes a-Si, and the first thickness of the active layer in the source region and the second thickness of the active layer in the drain region respectively exceed the third thickness of the active layer in the channel region; (2) the gate insulator layer includes the first gate insulator layer, the second gate insulator layer, and the third gate insulator layer, the second gate insulator layer is located between the first gate insulator layer and the third gate insulator layer, and the material of the first gate insulator layer is the same as the material of the third gate insulator layer, while the material of the second gate insulator layer is different from the material of the first gate insulator layer. Therefore, under high voltage driving, the semiconductor structure provided in one or more embodiments of the disclosure is able to effectively reduce/suppress leakage current, so that the semiconductor structure is adapted to products with high voltage driving requirements, such as EPD, GOA, or the like.

It will be apparent to those skilled in the art that various modifications and variations may be made to the disclosed embodiments without departing from the scope or spirit of the disclosure. In view of the foregoing, it is intended that the disclosure covers modifications and variations provided they fall within the scope of the following claims and their equivalents.

What is claimed is:

1. A semiconductor structure, comprising:
a gate;
an active layer, disposed on the gate and having a source region, a drain region, and a channel region located between the source region and the drain region;
a gate insulator layer, disposed between the gate and the active layer;
a source, disposed above the source region and extending onto the gate insulator layer; and
a drain, disposed above the drain region and extending onto the gate insulator layer,
wherein the semiconductor structure at least satisfies one of following conditions:
(1) a material of the active layer comprises amorphous silicon, and a first thickness of the active layer in the source region and a second thickness of the active layer in the drain region are respectively greater than a third thickness of the active layer in the channel region;
(2) the gate insulator layer comprises a first gate insulator layer, a second gate insulator layer, and a third gate insulator layer, the second gate insulator layer is located between the first gate insulator layer and the third gate insulator layer, and a material of the first gate insulator layer is the same as a material of the third gate insulator layer, while a material of the second gate insulator layer is different from the material of the first gate insulator layer.

2. The semiconductor structure as claimed in claim 1, wherein the first thickness is equal to the second thickness, the third thickness is less than the first thickness, and the third thickness is less than 1500 angstroms.

3. The semiconductor structure as claimed in claim 1, wherein the first gate insulator layer has a first insulation thickness, the second gate insulator layer has a second insulation thickness, the third gate insulator layer has a third insulation thickness, and the second insulation thickness is less than the first insulation thickness and the third insulation thickness.

4. The semiconductor structure as claimed in claim 3, wherein the first insulation thickness is greater than the third insulation thickness.

5. The semiconductor structure as claimed in claim 1, wherein the second gate insulator layer is a plasma treatment layer.

6. The semiconductor structure as claimed in claim 5, wherein a material of the plasma treatment layer comprises silicon oxide, aluminum oxide, or titanium oxide.

7. The semiconductor structure as claimed in claim 1, wherein a material of the first gate insulator layer and a material of the third gate insulator layer comprise silicon nitride, respectively.

8. The semiconductor structure as claimed in claim 1, wherein the first gate insulator layer, the second gate insulator layer, and the third gate insulator layer are sequentially stacked on the gate.

9. The semiconductor structure as claimed in claim 8, wherein the first gate insulator layer, the second gate insulator layer, and the third gate insulator layer are arranged in a coplanar manner.

10. The semiconductor structure as claimed in claim 1, further comprising:
an ohmic contact layer, disposed between the source region of the active layer and the source and between the drain region of the active layer and the drain.
